(19) United States
(12) Patent Application Publication
(10) Pub. No.: US 2026/0033256 A1
(43) Pub. Date: Jan. 29, 2026

(54) METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventors: Arito OGAWA, Toyama-shi (JP); Atsuro SEINO, Toyama-shi (JP)

(73) Assignee: Kokusai Electric Corporation, Tokyo (JP)

(21) Appl. No.: 19/348,362

(22) Filed: Oct. 2, 2025

Related U.S. Application Data
(63) Continuation of application No. 18/439,445, filed on Feb. 12, 2024, now Pat. No. 12,451,360.
Application No. 18/439,445 is a continuation of application No. 18/085,970, filed on Dec. 21, 2022, now Pat. No. 11,915,938.
Application No. 18/085,970 is a continuation of application No. 16/800,744, filed on Feb. 25, 2020, now Pat. No. 11,538,688.
Application No. 16/800,744 is a continuation of application No. PCT/JP2018/011719, filed on Mar. 23, 2018.

(30) Foreign Application Priority Data
Sep. 25, 2017 (JP) 2017-183406

(51) Int. Cl. H01L 21/285; C23C 16/34; C23C 16/52

(52) U.S. Cl. CPC H01L 21/28568; C23C 16/34; C23C 16/52

(57) ABSTRACT

There is provided a method of manufacturing a semiconductor device, including forming a metal nitride film substantially not containing a silicon atom on a substrate by sequentially repeating: (a) supplying a metal-containing gas and a reducing gas, which contains silicon and hydrogen and does not contain a halogen, to the substrate in a process chamber by setting an internal pressure of the process chamber to a value which falls within a range of 130 Pa to less than 3,990 Pa during at least the supply of the reducing gas, wherein (a) includes a timing of simultaneously supplying the metal-containing gas and the reducing gas; (b) removing the metal-containing gas and the reducing gas that remain in the process chamber; (c) supplying a nitrogen-containing gas to the substrate; and (d) removing the nitrogen-containing gas remaining in the process chamber.

### CROSS-REFERENCE TO RELATED APPLICATIONS

This application is a continuation application of U.S. patent application Ser. No. 18/085,970, filed Dec. 21, 2022, which is a continuation application of U.S. patent application Ser. No. 16/800,744, filed Feb. 25, 2020, which is a Bypass Continuation Application of PCT International Application No. PCT/JP2018/011719, filed on Mar. 23, 2018, which claims the benefit of priority from Japanese Patent Application No. 2017-183406, filed on Sep. 25, 2017, the entire contents of which is incorporated herein by reference.

### TECHNICAL FIELD

The present disclosure relates to a method of manufacturing a semiconductor device, a substrate processing apparatus, and a recording medium.

### BACKGROUND

A tungsten (W) film, for example, is used for a control gate of a NAND-type flash memory having a three-dimensional structure, and a tungsten hexafluoride (WF₆) gas containing W is used for forming the W film. Further, a titanium nitride (TiN) film may be formed as a barrier film between the W film and an insulating film. The TiN film serves to enhance adhesion between the W film and the insulating film, and also to prevent fluorine (F) contained in the W film from diffusing into the insulating film and the film formation is generally performed using a titanium tetrachloride (TiCl₄) gas and an ammonia (NH₃) gas.

As described above, the TiN film used as the barrier film is formed using the TiCl₄ gas and the NH₃ gas, and there is hydrochloric acid (HCl) as a byproduct generated in the film-forming process. This HCl is adsorbed on the surface of the TiN film which results in reducing a deposition rate, or the like.

### SUMMARY

The present disclosure provides some embodiments of a technique capable of reducing a film formation inhibiting factor of a metal film by supplying a reducing gas that reacts with a byproduct generated in a film-forming process into a process chamber and discharging it to an outside of the process chamber.

According to one embodiment of the present disclosure, there is provided a technique that forms a metal nitride film substantially not containing a silicon atom on a substrate by sequentially repeating: (a) supplying a metal-containing gas and a reducing gas, which contains silicon and hydrogen and does not contain a halogen, to the substrate by setting an internal pressure of a process chamber to a value which falls within a range of 130 Pa to less than 3,990 Pa during at least the supply of the reducing gas, wherein (a) includes a timing of simultaneously supplying the metal-containing gas and the reducing gas; (b) removing the metal-containing gas and the reducing gas that remain in the process chamber; (c) supplying a nitrogen-containing gas to the substrate; and (d) removing the nitrogen-containing gas remaining in the process chamber.

### BRIEF DESCRIPTION OF DRAWINGS

The accompanying drawings, which are incorporated in and constitute a part of the specification, illustrate embodiments of the present disclosure.

FIG. 1 is a vertical cross sectional view schematically illustrating a vertical type process furnace of a substrate processing apparatus according to an embodiment of the present disclosure.

FIG. 2 is a schematic cross sectional view taken along line A-A in FIG. 1.

FIG. 3 is a schematic configuration diagram of a controller of the substrate processing apparatus according to one embodiment of the present disclosure, in which a control system of the controller is shown in a block diagram.

FIG. 4 is a diagram illustrating a gas supply timing according to a first embodiment of the present disclosure.

FIG. 5 is a diagram illustrating an exemplary modification of the gas supply timing according to the first embodiment of the present disclosure.

FIG. 6 is a diagram illustrating a gas supply timing according to a second embodiment of the present disclosure.

FIG. 7 is a diagram illustrating an exemplary modification of the gas supply timing according to the second embodiment of the present disclosure.

FIG. 8 is a diagram illustrating a gas supply timing according to a third embodiment of the present disclosure.

FIG. 9 is a diagram illustrating an exemplary modification of the gas supply timing according to the third embodiment of the present disclosure.

FIG. 10 is a diagram illustrating a gas supply timing according to a fourth embodiment of the present disclosure.

FIG. 11 is a diagram illustrating an exemplary modification of the gas supply timing according to the fourth embodiment of the present disclosure.

FIG. 12 is a diagram illustrating a gas supply timing according to a comparative example of the present disclosure.

FIG. 13A is a diagram illustrating a deposition rate according to the present example and a deposition rate according to the comparative example, and FIG. 13B is a diagram illustrating a film composition of a TiN film formed according to the present example and a film composition of a TiN film formed according to the comparative example.

FIGS. 14A to 14C are diagrams illustrating XPS spectra of a TiN film formed according to the present example and a TiN film formed according to the comparative example, in which FIG. 14A illustrates a XPS spectrum of titanium (Ti2p), FIG. 14B illustrates a XPS spectrum of nitrogen (N1s), and FIG. 14C illustrates a XPS spectrum of chlorine (Cl2p).

FIG. 15 is a diagram illustrating a relationship among an internal pressure of a process chamber, a refractive index, and a film thickness when a SiH₄ gas is supplied.

FIG. 16 is a diagram illustrating a critical value of a supply time of a SiH₄ gas.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment of the Present Disclosure

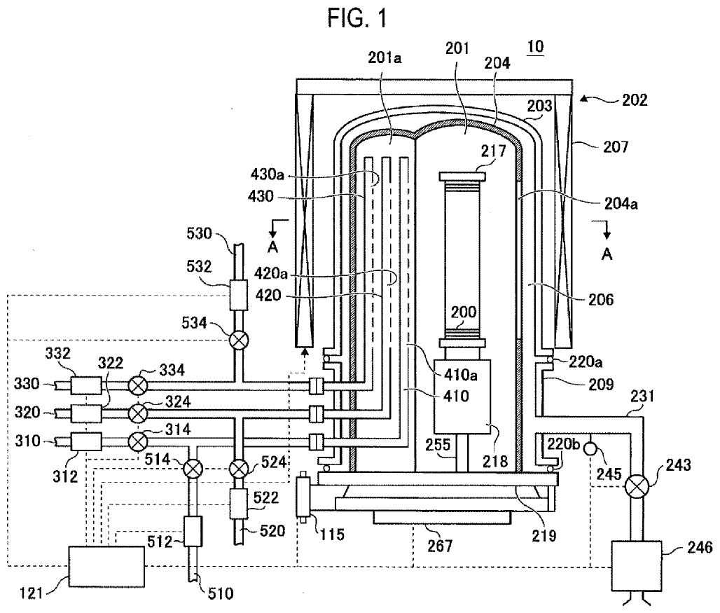

A first embodiment of the present disclosure will now be described with reference to FIGS. 1 to 4.

### (1) Configuration of the Substrate Processing Apparatus

A substrate processing apparatus 10 includes a process furnace 202 having a heater 207 as a heating means (a heating mechanism or a heating system) installed therein. The heater 207 has a cylindrical shape and is supported by a heater base (not shown) as a holding plate so as to be vertically installed.

An outer tube 203 constituting a reaction vessel (process vessel) is disposed inside the heater 207 to be concentric with the heater 207. The outer tube 203 is made of a heat resistant material, for example, quartz (SiO₂), silicon carbide (SiC) or the like, and has a cylindrical shape with its upper end closed and its lower end opened. A manifold (inlet flange) 209 is disposed below the outer tube 203 in a concentric relationship with the outer tube 203. The manifold 209 is made of a metal material such as, for example, stainless steel (SUS), and has a cylindrical shape with its upper and lower ends opened. An O-ring 220a as a seal member is installed between the upper end of the manifold 209 and the outer tube 203. The manifold 209 is supported by the heater base such that the outer tube 203 is vertically installed.

An inner tube 204 constituting the reaction vessel is disposed inside the outer tube 203. The inner tube 204 is made of a heat resistant material, for example, quartz (SiO₂), silicon carbide (SiC) or the like, and has a cylindrical shape with its upper end closed and its lower end opened. The process vessel (reaction vessel) is mainly configured by the outer tube 203, the inner tube 204, and the manifold 209. A process chamber 201 is formed in a hollow cylindrical portion (inside the inner tube 204) of the process vessel.

The process chamber 201 is configured to accommodate wafers 200 as substrates, in such a state that the wafers 200 are arranged in a horizontal posture and in multiple stages along a vertical direction in a boat 217 which will be described later.

Nozzles 410, 420, and 430 are installed in the process chamber 201 so as to penetrate a sidewall of the manifold 209 and the inner tube 204. Gas supply pipes 310, 320, and 330 are respectively connected to the nozzles 410, 420, and 430. However, the process furnace 202 of the present embodiment is not limited to the aforementioned configuration.

Mass flow controllers (MFCs) 312, 322, and 332, which are flow rate controllers (flow rate control parts), are installed in the gas supply pipes 310, 320, and 330 sequentially from the corresponding upstream sides, respectively. In addition, valves 314, 324, and 334, which are opening/closing valves, are installed in the gas supply pipes 310, 320, and 330, respectively. Gas supply pipes 510, 520, and 530, which supply an inert gas, are respectively connected to the gas supply pipes 310, 320 and 330 at the downstream side of the valves 314, 324, and 334. MFCs 512, 522, and 532, which are flow rate controllers (flow rate control parts), and valves 514, 524, and 534, which are opening/closing valves, are installed in the gas supply pipes 510, 520, and 530 sequentially from the corresponding upstream sides, respectively.

The nozzles 410, 420, and 430 are respectively connected to front end portions of the gas supply pipes 310, 320, and 330. The nozzles 410, 420, and 430 are configured as L-shaped nozzles. Horizontal portions of the nozzles 410, 420, and 430 are formed to penetrate the sidewall of the manifold 209 and the inner tube 204. Vertical portions of the nozzles 410, 420, and 430 are formed inside a channel-shaped (groove-shaped) preliminary chamber 201a formed to protrude outward of the inner tube 204 in a radial direction and extend along the vertical direction, and is also formed to extend upward along the inner wall of the inner tube 204 in the preliminary chamber 201a (upward in the arrangement direction of the wafers 200).

The nozzles 410, 420, and 430 are installed to extend from a lower region of the process chamber 201 to an upper region of the process chamber 201, and a plurality of gas supply holes 410a, 420a, and 430a are respectively formed at the opposite positions of the wafers 200, so as to allow a processing gas to be supplied from the gas supply holes 410a, 420a, and 430a of the nozzles 410, 420, and 430 to the wafers 200. The gas supply holes 410a, 420a, and 430a may be formed in a plural number between the lower portion of the inner tube 204 and the upper portion of the inner tube 204. The respective gas supply holes 410a, 420a, and 430a may have the same opening area and may be formed at the same opening pitch. However, the gas supply holes 410a, 420a, and 430a are not limited to the aforementioned configuration. For example, the opening arca may be gradually enlarged from the lower portion of the inner tube 204 to the upper portion of the inner tube 204. Thus, it is possible to make the flow rate of a gas supplied from the gas supply holes 410a, 420a and 430a more uniform.

The gas supply holes 410a, 420a, and 430a of the nozzles 410, 420, and 430 may be formed in a plural number at height positions from the lower portion of the boat 217 to the upper portion of the boat 217 as described later. Therefore, the processing gas, which is supplied from the gas supply holes 410a, 420a, and 430a of the nozzles 410, 420 and 430 into the process chamber 201, is supplied to an entire region of the wafers 200 accommodated from the lower portion of the boat 217 to the upper portion of the boat 217. The nozzles 410, 420, and 430 may be installed to extend from the lower region of the process chamber 201 to the upper region of the process chamber 201, but may be installed to extend up to near the ceiling of the boat 217.

A precursor gas (metal-containing gas) which contains a metal element, as the processing gas, is supplied from the gas supply pipe 310 into the process chamber 201 via the MFC 312, the valve 314, and the nozzle 410. As the precursor, it may be possible to use, for example, a titanium tetrachloride (TiCl₄) which contains titanium (Ti) as a metal element and which is a halogen-based precursor (a halide or a halogen-based titanium precursor).

A reducing gas as the processing gas is supplied from the gas supply pipe 320 into the process chamber 201 via the MFC 322, the valve 324, and the nozzle 420. As the reducing gas, it may be possible to use, for example, a silane (SiH₄) gas, as the reducing gas, for example, that contains silicon (Si) and hydrogen (H) and does not contain a halogen. The SiH₄ acts as a reducing agent.

A reaction gas as the processing gas is supplied from the gas supply pipe 330 into the process chamber 201 via the MFC 332, the valve 334, and the nozzle 430. As the reaction gas, it may be possible to use, for example, an ammonia (NH₃) gas as an N-containing gas containing, for example, nitrogen (N).

An inert gas, for example, a nitrogen (N₂) gas, is supplied from the gas supply pipes 510, 520, and 530 into the process chamber 201 via the MFCs 512, 522, and 532, the valves 514, 524, and 534, and the nozzles 410, 420, and 430. An example in which the N₂ gas is used as the inert gas will be described below, but a rare gas such as, for example, an argon (Ar) gas, a helium (He) gas, a neon (Ne) gas, a xenon (Xe) gas or the like, in addition to the N₂ gas, may be used as the inert gas.

Although a processing gas supply system is mainly configured by the gas supply pipes 310, 320, and 330, the MFCs 312, 322, and 332, the valves 314, 324, and 334, and the nozzles 410, 420, and 430, only the nozzles 410, 420 and 430 may be regarded as the processing gas supply system. The processing gas supply system may be simply referred to as a gas supply system. When a precursor gas is allowed to flow from the gas supply pipe 310, although a precursor gas supply system is mainly configured by the gas supply pipe 310, the MFC 312, and the valve 314, it may be regarded that the nozzle 410 is included in the precursor gas supply system. Furthermore, when a reducing gas is allowed to flow from the gas supply pipe 320, although a reducing gas supply system is mainly configured by the gas supply pipe 320, the MFC 322, and the valve 324, it may be regarded that the nozzle 420 is included in the reducing gas supply system. In addition, when a reaction gas is allowed to flow from the gas supply pipe 330, although a reaction gas supply system is mainly configured by the gas supply pipe 330, the MFC 332, and the valve 334, it may be regarded that the nozzle 430 is included in the reaction gas supply system. When a nitrogen-containing gas is supplied as the reaction gas from the gas supply pipe 330, the reaction gas supply system may be referred to as a nitrogen-containing gas supply system. Furthermore, an inert gas supply system is mainly configured by the gas supply pipes 510, 520, and 530, the MFC 512, 522, and 532, and the valves 514, 524, and 534.

In a gas supply method according to the present embodiment, a gas is transferred via the nozzles 410, 420, and 430, which are disposed in the preliminary chamber 201a in a vertically-elongated space with an annular shape which is defined by the inner wall of the inner tube 204 and the end portions of the wafers 200. The gas is injected from the gas supply holes 410a, 420a and 430a formed at the opposite positions of the nozzles 410, 420 and 430 from the wafers into the inner tube 204. More specifically, the precursor gas or the like is injected from the gas supply hole 410a of the nozzle 410, the gas supply hole 420a of the nozzle 420, and the gas supply hole 430a of the nozzle 430 in a direction parallel to the surfaces of the wafers 200.

An exhaust hole (exhaust port) 204a is a through hole formed on the sidewall of the inner tube 204 and at the opposite position of the nozzles 410, 420, and 430, and is, for example, a vertically-elongated slit-shaped through hole. A gas, which is supplied from the gas supply holes 410a, 420a, and 430a of the nozzles 410, 420, and 430 into the process chamber 201 and flows onto the surface of the wafer 200, flows through an exhaust passage as a gap formed between the inner tube 204 and the outer tube 203 through the exhaust hole 204a. Then, the gas flowing through the exhaust passage 206 flows through the exhaust pipe 231 and is discharged to the outside of the process furnace 202.

The exhaust hole 204a is formed at the opposite position of the wafers 200, and the gas supplied from the gas supply holes 410a, 420a, and 430a to near the wafers 200 in the process chamber 201 flows in the horizontal direction and then flows through the exhaust passage 206 through the exhaust hole 204a. The exhaust hole 204a is not limited to being configured as the slit-shaped through hole but may be configured as a plurality of holes.

An exhaust pipe 231, which is configured to exhaust an internal atmosphere of the process chamber 201, is installed in the manifold 209. A pressure sensor 245 as a pressure detector (pressure detection part) which detects the internal pressure of the process chamber 201, an auto pressure controller (APC) valve 243, and a vacuum pump 246 as a vacuum exhaust device are connected to the exhaust pipe 231 sequentially from the corresponding upstream side. The APC valve 243 is configured so that a vacuum exhaust of the interior of the process chamber 201 and a vacuum exhaust stop can be performed by opening and closing the APC valve 243 while operating the vacuum pump 246 and so that the internal pressure of the process chamber 201 can be adjusted by adjusting an opening degree of the APC valve 243 while operating the vacuum pump 246. An exhaust system is mainly configured by the exhaust hole 204a, the exhaust passage 206, the exhaust pipe 231, the APC valve 243, and the pressure sensor 245. It may be regarded that the vacuum pump 246 is included in the exhaust system.

A seal cap 219, which serves as a furnace opening cover configured to hermetically seal a lower end opening of the manifold 209, is installed under the manifold 209. The seal cap 219 is configured to make contact with the lower end portion of the manifold 209 from the lower side in the vertical direction. The seal cap 219 is made of metal such as, for example, stainless steel (SUS) or the like, and is formed in a disc shape. An O-ring 220b, which is a seal member making contact with the lower end portion of the manifold 209, is installed on an upper surface of the seal cap 219. A rotation mechanism 267 configured to rotate the boat 217 which accommodates the wafers 200 is installed at the opposite side of the process chamber 201 in the seal cap 219. A rotary shaft 255 of the rotation mechanism 267, which penetrates the seal cap 219, is connected to the boat 217. The rotation mechanism 267 is configured to rotate the wafers 200 by rotating the boat 217. The seal cap 219 is configured to be vertically moved up and down by a boat elevator 115 which is an elevator mechanism vertically installed outside the outer tube 203. The boat elevator 215 is configured to load and unload the boat 217 into and from the process chamber 201 by moving the seal cap 219 up and down. The boat elevator 215 is configured as a transfer device (transfer mechanism) which transfers the boat 217 and the wafers 200 accommodated in the boat 217 into and out of the process chamber 201.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 in a spaced-apart relationship. The boat 217 is made of a heat resistant material such as quartz or SiC. Heat insulating plates 218 made of a heat resistant material such as quartz or SiC are installed below the boat 217 in a horizontal posture and in multiple stages (not shown). With this configuration, it is hard for heat generated from the heater 207 to be transferred to the seal cap 219. However, the present embodiment is not limited to the aforementioned configuration. For example, instead of installing the heat insulating plates 218 below the boat 217, a heat insulating tube as a tubular member made of a heat resistant material such as quartz or SiC may be installed under the boat 217.

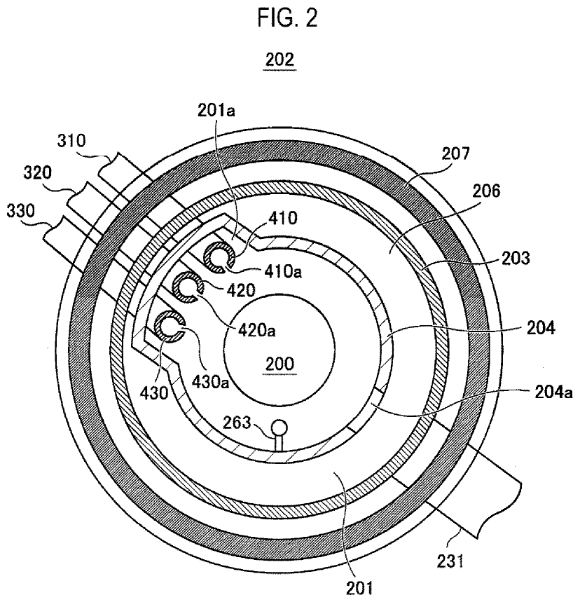

As illustrated in FIG. 2, a temperature sensor 263 serving as a temperature detector is installed in the inner tube 204. Based on temperature information detected by the temperature sensor 263, an amount of electric power supplied to the heater 207 is adjusted such that the interior of the process chamber 201 has a desired temperature distribution. Similar to the nozzles 410, 420 and 430, the temperature sensor 263 is formed in an L shape. The temperature sensor 263 is installed along the inner wall of the inner tube 204.

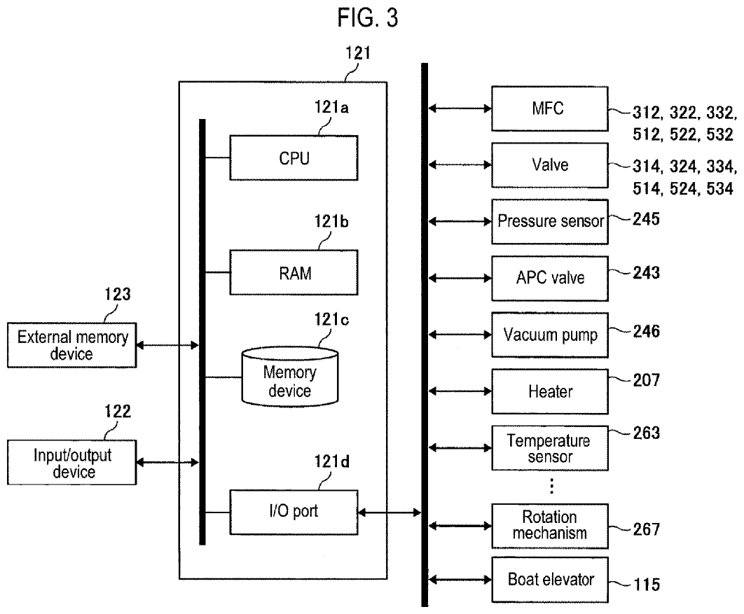

As illustrated in FIG. 3, a controller 121, which is a control part (control means), may be configured as a computer including a central processing unit (CPU) 121a, a random access memory (RAM) 121b, a memory device 121c, and an I/O port 121d. The RAM 121b, the memory device 121c and the I/O port 121d are configured to exchange data with the CPU 121a via an internal bus 121c. An input/output device 122 formed of, for example, a touch panel or the like, is connected to the controller 121.

The memory device 121c is configured by, for example, a flash memory, a hard disk drive (HDD), or the like. A control program for controlling operations of a substrate processing apparatus, a process recipe for specifying sequences and conditions of a method of manufacturing a semiconductor device as described later, or the like is readably stored in the memory device 121c. The process recipe functions as a program for causing the controller 121 to execute each process (each step) in the method of manufacturing a semiconductor device, as described later, to obtain a predetermined result. Hereinafter, the process recipe and the control program will be collectively and simply referred to as a “program.” When the term “program” is used herein, it may indicate a case of including only the process recipe, a case of including only the control program, or a case of including both the process recipe and the control program. The RAM 121b is configured as a memory area (work area) in which a program, data or the like read by the CPU 121a is temporarily stored.

The I/O port 121d is connected to the MFCs 312, 322, 332, 512, 52,2 and 532, the valves 314, 324, 514, 524, and 534, the pressure sensor 245, the APC valve 243, the vacuum pump 246, the heater 207, the temperature sensor 263, the rotation mechanism 267, the boat elevator 115, and the like, as described above.

The CPU 121a is configured to read the control program from the memory device 121c and execute the same. The CPU 121a also reads the recipe from the memory device 121c according to an input of an operation command from the input/output device 122. In addition, the CPU 121a is configured to control, according to the contents of the recipe thus read, the flow rate adjusting operation of various kinds of gases by the MFCs 312, 322, 332, 512, 522, and 532, the opening/closing operation of the valves 314, 324, 514, 524, and 534, the opening/closing operation of the APC valve 243, the pressure regulating operation performed by the APC valve 244 based on the pressure sensor 245, the temperature adjusting operation performed by the heater 207 based on the temperature sensor 263, the driving and stopping of the vacuum pump 246, the operation of rotating the boat 217 with the rotation mechanism 267 and adjusting the rotation speed of the boat 217, the operation of moving the boat 217 up and down with the boat elevator 115, the operation of accommodating the wafers 200 in the boat 217, and the like.

The controller 121 may be configured by installing, on the computer, the aforementioned program stored in an external memory device 123 (for example, a magnetic tape, a magnetic disc such as a flexible disc or a hard disc, an optical disc such as a CD or DVD, a magneto-optical disc such as an MO, or a semiconductor memory such as a USB memory or a memory card). The memory device 121c or the external memory device 123 is configured as a computer-readable recording medium. Hereinafter, the memory device 121c and the external memory device 123 will be collectively and simply referred to as a “recording medium.” In the present disclosure, the term “recording medium” may indicate a case of including only the memory device 121c, a case of including only the external memory device 123, or a case of including both the memory device 121c and the external memory device 123. Furthermore, the program may be supplied to the computer using a communication means such as the Internet or a dedicated line, instead of using the external memory device 123.

### (2) Substrate Processing (Film-Forming Process)

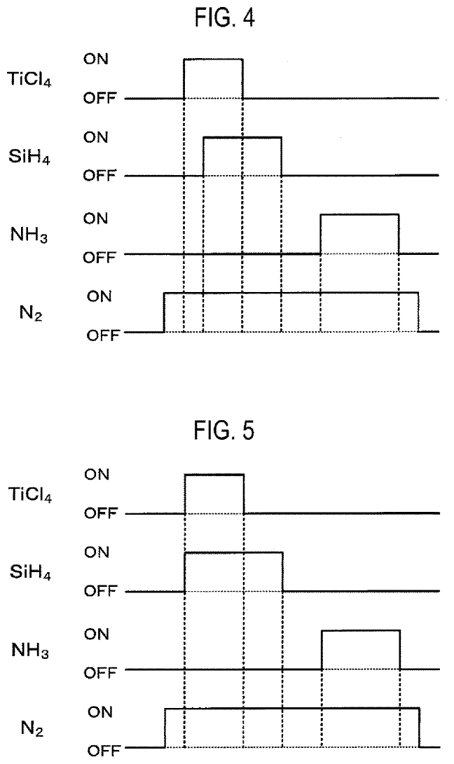

An example of a process of forming, for example, a metal film constituting a gate electrode on a wafer 200, which is one of the processes for manufacturing a semiconductor device, will be described with reference to FIG. 4. The process of forming a metal film is performed using the process furnace 202 of the aforementioned substrate processing apparatus 10. In the following descriptions, the operations of the respective parts constituting the substrate processing apparatus 10 are controlled by the controller 121.

In the substrate processing (a process of manufacturing a semiconductor device) according to the present embodiment, a TiN film substantially not containing a silicon atom on a wafer is formed by sequentially repeating: a first step of supplying a TiCl₄ gas as a metal-containing gas, and a SiH₄ gas as a reducing gas, which contains silicon and hydrogen and does not containing a halogen, to the substrate by setting an internal pressure of the process chamber 201 to a value which falls within a range of 130 Pa to less than 3,990 Pa during at least the supply of the SiH₄ gas, wherein the first step includes a timing of simultaneously supplying the TiCl₄ gas and the SiH₄ gas; a second step of removing the TiCl₄ gas and the SiH₄ gas that remain in the process chamber 201; a third step of supplying an NH₃ gas as a nitrogen-containing gas to the wafer 200; and a fourth step of removing the NH₃ gas remaining in the process chamber 201.

When the term “wafer” is used herein, it may refer to “a wafer itself” or “a laminated body of a wafer and a predetermined layer or film formed on the surface of the wafer”. In addition, when the phrase “a surface of a wafer” is used herein, it may refer to “a surface of a wafer itself” or “a surface of a predetermined layer or film formed on a wafer”. Furthermore, when the term “substrate” is used herein, it may be synonymous with the term “wafer.”

In addition, in the present disclosure, the phrase “TiN film containing no Si atom” may include a case where a Si content in the TiN film is very low, for example, a case where a Si content in the TiN film is about 4% or 4% or less in some embodiments, such as a case where the TiN film contains almost no Si atom or a case where the TiN film contains substantially no Si atom film, in addition to a case where the TiN film contains no Si atom.

### (Wafer Loading)

If a plurality of wafers 200 is charged on the boat 217 (wafer charging), as illustrated in FIG. 1, the boat 217 supporting the plurality of wafers 200 is lifted up by the boat elevator 115 and is loaded into the process chamber 201 (boat loading). In this state, the seal cap 219 seals the lower end of the reaction tube 203 through the O-ring 220.

### (Pressure Regulation and Temperature Adjustment)

The interior of the process chamber 201 is vacuum-exhausted by the vacuum pump 246 so as to reach a desired pressure (degree of vacuum). In this operation, the internal pressure of the process chamber 201 is measured by the pressure sensor 245. The APC valve 243 is feedback-controlled based on the measured pressure information (pressure regulation). The vacuum pump 246 may be continuously activated at least until the processing of the wafers 200 is completed. Furthermore, the interior of the process chamber 201 is heated by the heater 207 to a desired temperature. In this operation, the amount of electric power supplied to the heater 207 is feedback-controlled based on the temperature information detected by the temperature sensor 263 such that the interior of the process chamber 201 has a desired temperature distribution (temperature adjustment). The heating of the interior of the process chamber 201 by the heater 207 may be continuously performed at least until the processing of the wafers 200 is completed.

### [First Step]

### (TiCl₄ Gas Supply)

The valve 314 is opened to allow a TiCl₄ gas as a precursor gas to flow through the gas supply pipe 310. The flow rate of the TiCl₄ gas is adjusted by the MFC 312. The TiCl₄ gas is supplied from the gas supply hole 410a of the nozzle 410 into the process chamber 201 and is exhausted from the exhaust pipe 231. At this time, the TiCl₄ gas is supplied to the wafer 200. Simultaneously, the valve 514 is opened to allow an inert gas such as an N₂ gas to flow through the gas supply pipe 510. The flow rate of the N₂ gas flowing through the gas supply pipe 510 is adjusted by the MFC 512. The N₂ gas is supplied to the process chamber 201 together with the TiCl₄ gas and is exhausted from the exhaust pipe 231. At this time, in order to prevent the TiCl₄ gas from entering the nozzles 420 and 430, the valves 524 and 534 are opened to allow the N₂ gas to flow through the gas supply pipes 520 and 530. The N₂ gas is supplied into the process chamber 201 via the gas supply pipes 320 and 330 and the nozzles 420 and 430 and is exhausted from the exhaust pipe 231.

At this time, the internal pressure of the process chamber 201 may be set at a pressure which falls within a range of, for example, 1 to 3,990 Pa, by adjusting the APC valve 243. The supply flow rate of the TiCl₄ gas controlled by the MFC 312 may be set at a flow rate which falls within a range of, for example, 0.1 to 2.0 slm. The supply flow rates of the N₂ gas controlled by the MFCs 512, 522, and 532 may be respectively set at a flow rate which falls within a range of, for example, 0.1 to 20 slm. At this time, the temperature of the heater 207 is set such that the temperature of the wafer 200 becomes a temperature which falls within a range of, 300 to 600 degrees C.

At this time, the gases flowing through the process chamber 201 are only the TiCl₄ gas and the N₂ gas. By supplying the TiCl₄ gas, a Ti-containing layer is formed on the wafer 200 (an underlying film on its surface). The Ti-containing layer may be a Ti layer containing Cl or an adsorption layer of TiCl₄, or may include both of them.

### (SiH₄ Gas Supply)

After a lapse of a predetermined time, for example, after 0.01 to 5 seconds, from the start of the supply of the TiCl₄ gas, the valve 324 is opened to allow a SiH₄ gas as a reducing gas to flow through the gas supply pipe 320. The flow rate of the SiH₄ gas is adjusted by the MFC 322. The SiH₄ gas is supplied from the gas supply hole 420a of the nozzle 420 into the process chamber 201 and is exhausted from the exhaust pipe 231. Simultaneously, the valve 524 is opened to allow an inert gas such as an N₂ gas to flow through the gas supply pipe 520. The flow rate of the N₂ gas flowing through the gas supply pipe 520 is adjusted by the MFC 522. The N₂ gas is supplied into the process chamber 201 together with the SiH₄ gas and is exhausted from the exhaust pipe 231. At this time, in order to prevent the TiCl₄ gas and the SiH₄ gas from entering the nozzle 430, the valve 534 is opened to allow the N₂ gas to flow through the gas supply pipe 530. The N₂ gas is supplied into the process chamber 201 via the gas supply pipe 330 and the nozzle 430 and is exhausted from the exhaust pipe 231. At this time, the TiCl₄ gas, the SiH₄ gas, and the N₂ gas are simultaneously supplied to the wafer 200. That is, at least the TiCl₄ gas and the SiH₄ gas have a timing to be simultaneously supplied.

At this time, the internal pressure of the process chamber 201 may be set at a pressure which falls within a range of, for example, 130 to 3,990 Pa, specifically 500 to 2,660 Pa, or more specifically 900 to 1,500 Pa, by adjusting the APC valve 243. If the internal pressure of the process chamber 201 is lower than 130 Pa, Si contained in the SiH₄ gas enters the Ti-containing layer so that the Si content (in the film) contained in the formed TiN film may be increased to become a TiSiN film. Similarly, if the internal pressure of the process chamber 201 is higher than 3,990 Pa, Si contained in the SiH₄ gas enters the Ti-containing layer so that the Si content contained in the formed TiN film may be increased to become a TiSiN film. As described above, if the internal pressure of the process chamber 201 is too low or too high, the element composition of the formed film is varied. The supply flow rate of the SiH₄ gas controlled by the MFC 322 may be set at a flow rate which falls within a range of, for example, 0.1 to 5 slm, specifically 0.5 to 3 slm, or more specifically 1 to 2 slm. The supply flow rates of the N₂ gas controlled by the MFCs 512, 522, and 532 may be respectively set at a flow rate which falls within a range of, for example, 0.01 to 20 slm, specifically 0.1 to 10 slm, or more specifically 0.1 to 1 slm. At this time, the temperature of the heater 207 may be set at the same temperature as that used at the TiCl₄ gas supply step.

After a lapse of a predetermined time, for example, after 0.01 to 10 seconds, from the start of the supply of the TiCl₄ gas, the valve 314 of the gas supply pipe 310 is closed to stop the supply of the TiCl₄ gas. That is, the time for supplying the TiCl₄ gas to the wafer 200 may be set at a time within a range of, for example, 0.01 to 10 seconds. At this time, in order to prevent the SiH₄ gas from entering the nozzles 410 and 430, the valves 514 and 534 are opened to allow the N₂ gas to flow through the gas supply pipes 510 and 530. The N₂ gas is supplied into the process chamber 201 via the gas supply pipes 310 and 330 and the nozzles 410 and 430, and then exhausted from the exhaust pipe 231. At this time, the SiH₄ gas and the N₂ gas are supplied to the wafer 200.

### [Second Step]

### (Residual Gas Removal)

After a lapse of a predetermined time, for example, after 0.01 to 60 seconds, specifically 0.1 to 30 seconds, or more specifically 1 to 20 seconds, from the start of the supply of the SiH₄ gas, the valve 324 is closed to stop the supply of the SiH₄ gas. That is, the time for supplying the SiH₄ gas to the wafer 200 may be set at a time within a range of, for example, 0.01 to 60 seconds, specifically 0.1 to 30 seconds, or more specifically 1 to 20 seconds. If the time for supplying the SiH₄ gas to the wafer 200 is shorter than 0.01 second, there is a possibility that HCl, which is a growth inhibiting factor, is not sufficiently reduced by the SiH₄ gas and remains in the Ti-containing layer. If the time for supplying the SiH₄ gas to the wafer 200 is longer than 60 seconds, there is a possibility that Si contained in the SiH₄ gas enters the Ti-containing layer so that the Si content contained in the formed TiN film may be increased to become a TiSiN film. At this time, the interior of the process chamber 201 is vacuum-exhausted by the vacuum pump 246 while keeping the APC valve 243 of the exhaust pipe 231 opened, and the unreacted TiCl₄ gas and SiH₄ gas or the TiCl₄ gas and SiH₄ gas after contribution to the formation of the Ti-containing layer, which remain in the process chamber 201, are removed from the interior of the process chamber 201. At this time, the supply of the N₂ gas into the process chamber 201 is maintained while keeping the valves 514, 524, and 534 opened. The N₂ gas acts as a purge gas. This makes it possible to enhance the effect of removing the unreacted TiCl₄ gas and SiH₄ gas or the TiCl₄ gas and SiH₄ gas after the contribution to the formation of the Ti-containing layer, which remain in the process chamber 201, from the interior of the process chamber 201. At this time, HCl, which is a growth inhibiting factor, reacts with SiH₄ to be discharged from the interior of the process chamber 201 as silicon tetrachloride (SiCl₄) and H₂.

### [Third Step]

### (NH₃ Gas Supply)

After the residual gas in the process chamber 201 is removed, the valve 334 is opened to allow an NH₃ gas as a reaction gas to flow through the gas supply pipe 330. The flow rate of the NH₃ gas is adjusted by the MFC 332. The NH₃ gas is supplied from the gas supply hole 430a of the nozzle 430 into the process chamber 201 and is exhausted from the exhaust pipe 231. At this time, the NH₃ gas is supplied to the wafer 200. Simultaneously, the valve 534 is opened to allow an N₂ gas to flow through the gas supply pipe 530. The flow rate of the N₂ gas flowing through the gas supply pipe 530 is adjusted by the MFC 532. The N₂ gas is supplied into the process chamber 201 together with the NH₃ gas and is exhausted from the exhaust pipe 231. At this time, in order to prevent the NH₃ gas from entering the nozzles 410 and 420, the valves 514 and 524 are opened to allow the N₂ gas to flow through the gas supply pipes 510 and 520. The N₂ gas is supplied into the process chamber 201 via the gas supply pipes 310 and 320 and the nozzles 410 and 420 and is exhausted from the exhaust pipe 231.

At this time, the internal pressure of the process chamber 201 may be set at a pressure which falls within a range of, for example, 1 to 3,990 Pa, by adjusting the APC valve 243. The supply flow rate of the NH₃ gas controlled by the MFC 332 may be set at a flow rate which falls within a range of, for example, 0.1 to 30 slm. The supply flow rates of the N₂ gas controlled by the MFCs 512, 522, and 532 may be respectively set at a flow rate which falls within a range of, for example, 0.1 to 30 slm. The time, during which the NH₃ gas is supplied to the wafer 200, may be set at a time which falls within a range of, for example, 0.01 to 30 seconds. The temperature of the heater 207 at this time may be set at the same temperature as that used at the TiCl₄ gas supply step.

At this time, the gases flowing through the process chamber 201 are only the NH₃ gas and the N₂ gas. The NH₃ gas undergoes a substitution reaction with at least a portion of the Ti-containing layer formed on the wafer 200 at the first step. During the substitution reaction, Ti contained in the Ti-containing layer and N contained in the NH₃ gas are combined to form a TiN layer containing Ti and N and containing substantially no Si on the wafer 200.

### [Fourth Step]

### (Residual Gas Removal)

After the TiN layer is formed, the valve 334 is closed to stop the supply of the NH₃ gas.

Then, the unreacted NH₃ gas, the NH₃ gas after the contribution to the formation of the TiN layer, or the reaction byproduct, which remains in the process chamber 201, are removed from the interior of the process chamber 201 according to the same processing procedures as those of the second step described above.

### (Performing a Predetermined Number of Times)

A cycle which sequentially performs the first to fourth steps described above is implemented once or more (a predetermined number of times (n times)), whereby a TiN film having a predetermined thickness (e.g., 0.5 to 5.0 nm) can be formed on the wafer 200. The aforementioned cycle may be repeated multiple times.

### (After-Purge and Atmospheric Pressure Return)

The N₂ gas is supplied from each of the gas supply pipes 510, 520, and 530 into the process chamber 201 and is exhausted from the exhaust pipe 231. The N₂ gas acts as a purge gas to thereby purge the interior of the process chamber 201 with an inert gas, so that the gas or the reaction byproduct, which remains in the process chamber 201, is removed from the interior of the process chamber 201 (after-purge). Thereafter, the internal atmosphere of the process chamber 201 is substituted by an inert gas (inert gas substitution). The internal pressure of the process chamber 201 is returned to an atmospheric pressure (atmospheric pressure return).

### (Wafer Unloading)

Next, the seal cap 219 is moved down by the boat elevator 115 to open the lower end of the reaction tube 203. Then, the processed wafers 200 supported on the boat 217 are unloaded from the lower end of the reaction tube 203 to the outside of the reaction tube 203 (boat unloading). Thereafter, the processed wafers 200 are discharged from the boat 217 (wafer discharging).

(3) Effects according to the First Embodiment

According to the present embodiment, one or more effects as set forth below may be achieved.
(a) It is possible to efficiently discharge HCl which is generated during film formation and lowers the deposition rate, and to raise the deposition rate.
(b) It is possible to lower the resistivity.
(c) It is possible to improve the oxidation resistance.

### (4) Exemplary Modification

In a modification of the first embodiment described above, as illustrated in FIG. 5, at the first step described above, the only difference is that the supply of the SiH₄ gas starts simultaneously with the supply of the TiCl₄ gas, and the supply of the TiCl₄ gas is stopped and then the supply of the SiH₄ gas is stopped, and the second to fourth steps are similar to those of the first embodiment described above. Even in this modification, the same effects as those of the film-forming sequence illustrated in FIG. 4 may be achieved. In the first embodiment and the modification described above, there has been described a configuration in which after the supply of the TiCl₄ gas and the supply of the SiH₄ gas are simultaneously performed, the supply of the TiCl₄ gas is stopped and then the SiH₄ gas is continuously supplied and stopped. However, the present disclosure is not limited thereto, but after the supply of the TiCl₄ gas and the supply of the SiH₄ gas are simultaneously performed, the residual gas may be removed by simultaneously stopping the gas supply. However, the configuration of stopping the supply of the TiCl₄ gas, continuously supplying the SiH₄ gas and then stopping the supply the SiH₄ gas in the first embodiment and the modification described above makes Si concentration to be lower. This is because HCl, which is the reaction byproduct, reacts with SiH₄ to be discharged in the form of SiCl₄, without giving time to adsorb on the wafer surface.

### Second Embodiment

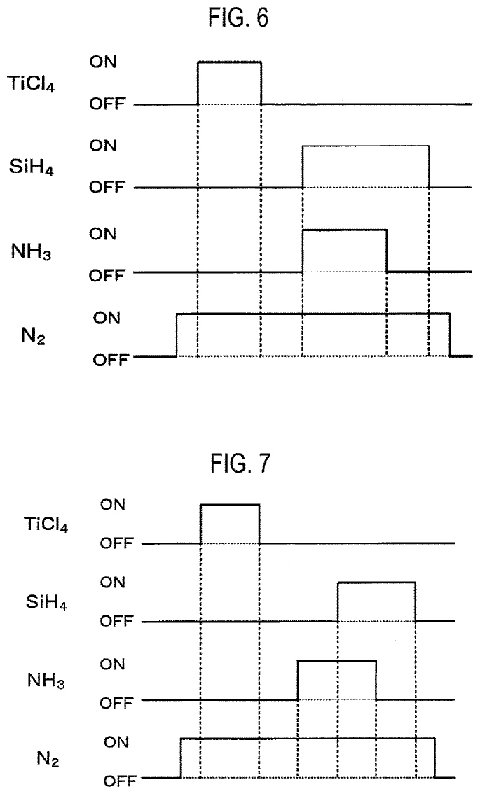

FIG. 6 is a diagram illustrating a gas supply timing according to a second embodiment of the present disclosure, applied to the present embodiment. In the following embodiment, only the gas supply timing will be described in detail.

### [First Step]

### (TiCl₄ Gas Supply)

A TiCl₄ gas is supplied into the process chamber 201 according to the same processing procedures as those of the TiCl₄ gas supply step at the first step of the first embodiment. At this time, the gases flowing through the process chamber 201 are only the TiCl₄ gas and an N₂ gas, and a Ti-containing layer is formed on the wafer 200 (an underlying film on its surface) by the supply of the TiCl₄ gas.

### [Second Step]

### (Residual Gas Removal)

After the Ti-containing layer is formed, the unreacted TiCl₄ gas or the TiCl₄ gas after the contribution to the formation of the Ti-containing layer, which remains in the process chamber 201, is removed from the interior of the process chamber 201 according to the same processing procedures as those of the second step of the first embodiment.

### [Third Step]

### (NH₃ Gas Supply)

After the residual gas in the process chamber 201 is removed, an NH₃ gas is supplied into the process chamber 201 according to the same processing procedures as those of the NH₃ gas supply step of the first embodiment.

### (SiH₄ Gas Supply)

Simultaneously, the valve 324 is opened to supply a SiH₄ gas into the process chamber 201 according to the same processing procedures as those of the SiH₄ gas supply step of the first embodiment. Furthermore, at this time, in order to prevent the NH₃ gas and the SiH₄ gas from entering the nozzle 410, the point that the valve 514 is opened to allow an N₂ gas to flow through the gas supply pipe 510 is different from the SiH₄ gas supply step of the first embodiment. The N₂ gas is supplied into the process chamber 201 via the gas supply pipe 310 and the nozzle 410 and is exhausted from the exhaust pipe 231. At this time, the SiH₄ gas, the NH₃ gas, and the N₂ gas are supplied to the wafer 200. At this time, the NH₃ gas undergoes a substitution reaction with at least a portion of the Ti-containing layer formed on the wafer 200 at the first step. During the substitution reaction, Ti contained in the Ti-containing layer and N contained in the NH₃ gas are combined to form a TiN layer containing Ti and N on the wafer 200.

After a lapse of a predetermined time from the start of the supply of the NH₃ gas, the valve 334 of the gas supply pipe 330 is closed to stop the supply of the NH₃ gas. At this time, in order to prevent the SiH₄ gas from entering the nozzles 410 and 430, the valves 514 and 534 are opened to allow the N₂ gas to flow through the gas supply pipes 510 and 530. The N₂ gas is supplied into the process chamber 201 via the gas supply pipes 310 and 330 and the nozzles 410 and 430 and is exhausted from the exhaust pipe 231. At this time, the SiH₄ gas and the N₂ gas are supplied to the wafer 200.

### [Fourth Step]

### (Residual Gas Removal)

After a lapse of a predetermined time since the TiN layer have been formed and the supply of the SiH₄ gas has started, the valve 324 is closed to stop the supply of the SiH₄ gas. At this time, the interior of the process chamber 201 is vacuum-exhausted by the vacuum pump 246 while keeping the APC valve 243 of the exhaust pipe 231 opened, and the unreacted NH₃ gas, the NH₃ gas after the contribution to the formation of the TiN layer, or the reaction byproduct, which remains in the process chamber 201, is removed from the interior of the process chamber 201 according to the same processing procedures as those of the second step described above. At this time, HCl, which is a growth inhibiting factor, reacts with SiH₄ to be discharged from the interior of the process chamber 201 as SiCl₄ and H₂.

### (Performing a Predetermined Number of Times)

A cycle which sequentially performs the first step to fourth steps described above is implemented once or more (a predetermined number of times (n times)), whereby a TiN film having a predetermined thickness can be formed on the wafer 200.

### (2) Effects According to the Second Embodiment

According to the present embodiment, one or more effects as set forth below may be achieved.
(a) It is possible to suppress the formation of NH₄Cl due to the reaction between HCl and NH₃.

### (3) Exemplary Modification

In a modification of the second embodiment described above, as illustrated in FIG. 7, at the third step described above, the only difference is that after a lapse of a predetermined time from the start of the supply of the NH₃ gas, the supply of the SiH₄ gas as the reducing gas starts, the supply of the NH₃ gas is stopped and then the supply of the SiH₄ gas is stopped, and the first step, the second step, and the fourth step are similar to those of the second embodiment described above. Even in this modification, the same effects as those of the film-forming sequence illustrated in FIG. 6 may be achieved.

### Third Embodiment

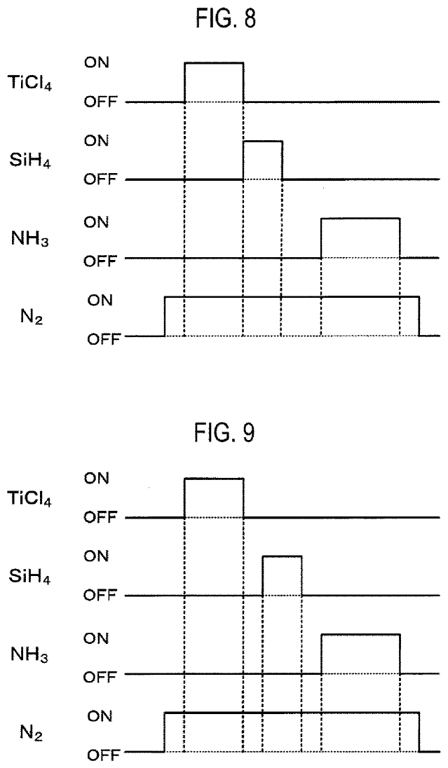

FIG. 8 is a diagram illustrating a gas supply timing according to a third embodiment of the present disclosure.

### [First Step]

### (TiCl₄ Gas Supply)

A TiCl₄ gas is supplied into the process chamber 201 according to the same processing procedures as those of the TiCl₄ gas supplying step at the first step of the first embodiment. At this time, the gases flowing through the process chamber 201 are only the TiCl₄ gas and a N₂ gas, and a Ti-containing layer is formed on the wafer 200 (an underlying film on its surface) by the supply of the TiCl₄ gas.

### [Second Step]

### (SiH₄ Gas Supply)

The valve 314 of the gas supply pipe 310 is closed to stop the supply of the TiCl₄ gas. Simultaneously, the valve 324 is opened to allow a SiH₄ gas as a reducing gas to flow through the gas supply pipe 320 according to the same processing procedures as those of the SiH₄ gas supply step at the first step of the first embodiment. That is, the supply of the TiCl₄ gas and the supply of the SiH₄ gas are continuously performed. At this time, the SiH₄ gas and the N₂ gas are supplied to the wafer 200.

### [Third Step]

### (Residual Gas Removal)

The valve 324 is closed to stop the supply of the SiH₄ gas. That is, at this time, the interior of the process chamber 201 is vacuum-exhausted by the vacuum pump 246 while keeping the APC valve 243 of the exhaust pipe 231 opened, and the unreacted TiCl₄ gas and SiH₄ gas or the TiCl₄ gas and SiH₄ gas after the contribution to the formation of the Ti-containing layer, which remain in the process chamber 201, are removed from the interior of the process chamber 201. At this time, the supply of the N₂ gas into the process chamber 201 is maintained while keeping the valves 514, 524 and 534 opened. The N₂ gas acts as a purge gas. This makes it possible to enhance the effect of removing the unreacted TiCl₄ gas and SiH₄ gas or the TiCl₄ gas and SiH₄ gas after the contribution to the formation of the Ti-containing layer, which remain in the process chamber 201, from the interior of the process chamber 201. At this time, HCl, which is a growth inhibiting factor, reacts with SiH₄ to be discharged from the interior of the process chamber 201 as SiCl₄ and H₂.

### [Fourth Step]

### (NH₃ Gas Supply)

After the residual gas in the process chamber 201 is removed, an NH₃ gas, which is an N-containing gas as a reaction gas, is allowed to flow through the gas supply pipe 330 according to the same processing procedures as those of the NH₃ gas supply step at the third step of the first embodiment. At this time, the gases flowing through the process chamber 201 are only the NH₃ gas and an N₂ gas. The NH₃ gas undergoes a substitution reaction with at least a portion of the Ti-containing layer formed on the wafer 200 at the first step. During the substitution reaction, Ti contained in the Ti-containing layer and N contained in the NH₃ gas are bonded to form a TiN layer containing Ti and N on the wafer 200.

### [Fifth Step]

### (Residual Gas Removal)

After the TiN layer is formed, the valve 334 is closed to stop the supply of the NH₃ gas.

Then, the unreacted NH₃ gas, the NH₃ gas after the contribution to the formation of the TiN layer, or the reaction byproduct, which remains in the process chamber 201, is removed from the interior of the process chamber 201 according to the same processing procedures as those of the third step described above.

### (Performing a Predetermined Number of Times)

A cycle which sequentially performs the first step to fifth steps described above is implemented once or more (a predetermined number of times (n times)), whereby a TiN film having a predetermined thickness can be formed on the wafer 200.

### (2) Effects According to the Third Embodiment

According to the present embodiment, one or more effects as set forth below may be achieved.
(a) It is possible to discharge HCl generated after the supply of the TiCl₄ gas to the outside of the reaction tube by reacting it with SiH₄.

### (3) Exemplary Modification

In a modification of the third embodiment described above, as illustrated in FIG. 9, the only difference is that it includes a step of removing the residual gas in the process chamber 201 between the first step of supplying the TiCl₄ gas and the second step of supplying the SiH₄ gas of the third embodiment described above. Even in this modification, the same effects as those of the film-forming sequence illustrated in FIG. 8 may be achieved.

### Fourth Embodiment

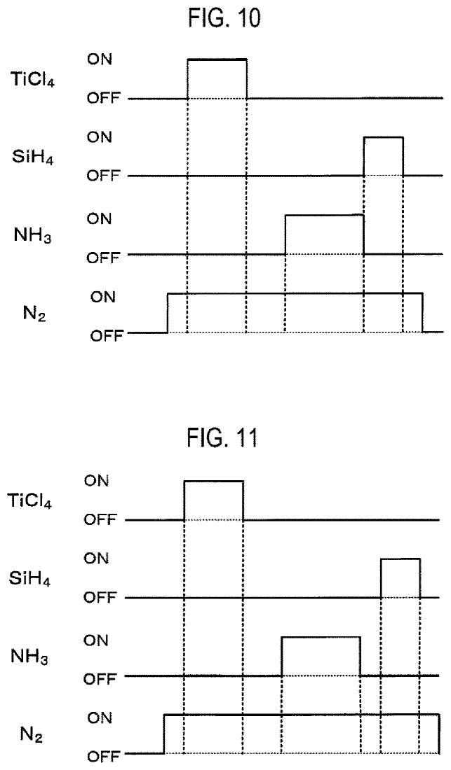

FIG. 10 is a diagram illustrating a gas supply timing according to a fourth embodiment of the present disclosure.

### [First Step]

### (TiCl₄ Gas Supply)

The valve 314 is opened to supply a TiCl₄ gas into the process chamber 201 according to the same processing procedures as those of the TiCl₄ gas supply step at the first step of the first embodiment. At this time, the gases flowing through the process chamber 201 are only the TiCl₄ gas and an N₂ gas, and a Ti-containing layer is formed on the wafer 200 (an underlying film on its surface) by the supply of the TiCl₄ gas.

### [Second Step]

### (Residual Gas Removal)

The unreacted TiCl₄ gas or the TiCl₄ gas after the contribution to the formation of the Ti-containing layer, which remains in the process chamber 201, is removed from the interior of the process chamber 201 according to the same processing procedures as those of the residual gas removal step at the second step of the first embodiment.

### [Third Step]

### (NH₃ Gas Supply)

An NH₃ gas, which is a N-containing gas as a reaction gas, is allowed to flow through the process chamber 201 according to the same processing procedures as those of the NH₃ gas supply step at the first step of the first embodiment. At this time, the gases flowing through the process chamber 201 are only the NH₃ gas and a N₂ gas. The NH₃ gas undergoes a substitution reaction with at least a portion of the Ti-containing layer formed on the wafer 200 at the first step. During the substitution reaction, Ti contained in the Ti-containing layer and N contained in the NH₃ gas are combined to form a TiN layer containing Ti and N on the wafer 200.

### [Fourth Step]

### (SiH₄ Gas Supply)

The valve 334 of the gas supply pipe 330 is closed to stop the supply of the NH₃ gas. Simultaneously, the valve 324 is opened to allow a SiH₄ gas as a reducing gas to flow through the process chamber 201 according to the same processing procedures as the SiH₄ gas supply step at the first step of the first embodiment. That is, the NH₃ gas supply and the SiH₄ gas supply are continuously performed.

### [Fifth Step]

### (Residual Gas Removal)

The valve 324 is closed to stop the supply of the SiH₄ gas. That is, at this time, the interior of the process chamber 201 is vacuum-exhausted by the vacuum pump 246 while keeping the APC valve 243 of the exhaust pipe 231 opened, and the unreacted NH₃ gas, the NH₃ gas after the contribution to the formation of the TiN layer, or the reaction byproduct, which remains in the process chamber 201, is removed from the interior of the process chamber 201. At this time, HCl, which is a growth inhibiting factor, reacts with SiH₄ to be discharged from the interior of the process chamber 201 as SiCl₄ and H₂.

### (Performing a Predetermined Number of Times)

A cycle which sequentially performs the first step to fifth steps described above is implemented once or more (a predetermined number of times (n times)), whereby a TiN film having a predetermined thickness can be formed on the wafer 200.

### (2) Effects According to the Third Embodiment

According to the present embodiment, one or more effects as set forth below may be achieved.
(a) It is possible to discharge HCl remaining after the supply of the NH₃ gas to the outside of the reaction tube by reacting it with SiH₄.

### (3) Exemplary Modification

In a modification of the fourth embodiment described above, as illustrated in FIG. 11, the only difference is that it includes a step of removing the residual gas within the process chamber 201 between the third step of supplying the NH₃ gas and the fourth step of supplying the SiH₄ gas of the fourth embodiment described above. Even in this modification, the same effects as those of the film-forming sequence illustrated in FIG. 10 may be achieved.

An experimental example will be described below, but the present disclosure is not limited to the experimental example.

### Experimental Example

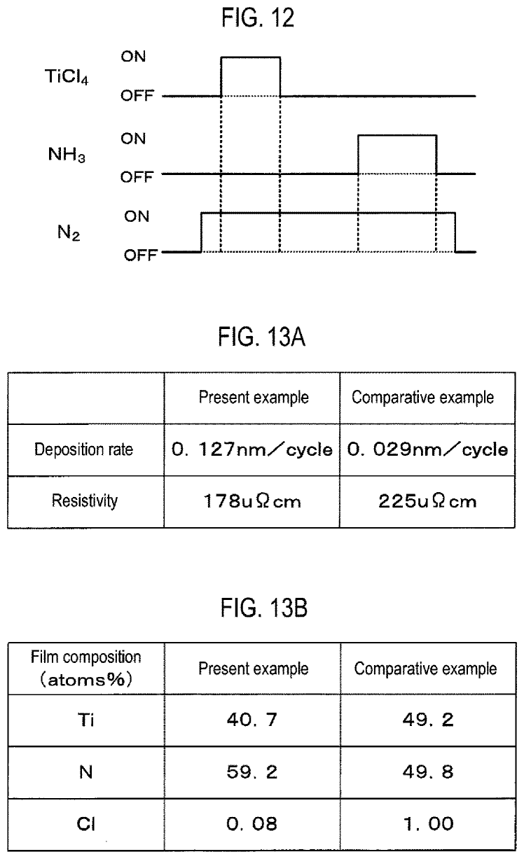

In this example, a TiN film was formed using the gas supply timing illustrated in FIG. 4 in the aforementioned embodiments. In a comparative example, a TiN film was formed using a gas supply timing illustrated in FIG. 12. Specifically, in the comparative example, the TiN film was formed by repeatedly performing the TiCl₄ gas supply, the residual gas removal, the NH₃ gas supply, and the residual gas removal.

As illustrated in FIG. 13A, the TiN film formed according to the comparative example had a deposition rate 0.029 nm/cycle and a resistivity of 225 uΩ2 cm, whereas the TiN film formed according to this example had a deposition rate of 0.127 nm/cycle and a resistivity of 178 uΩcm. That is, it could be confirmed that the TiN film formed according to this example had a higher deposition rate and a lower resistivity than the TiN film formed according to the comparative example.

Furthermore, as illustrated in FIG. 13B, a film composition of the TiN film formed according to the comparative example was 49.2% for Ti, 49.8% for N, and 1.0% for Cl, whereas a composition of the TiN film formed according to this example was 40.7% for Ti, 59.2% for N, and 0.08% for Cl. That is, it could be confirmed that the Cl concentration in the TiN film formed according to this example can be lower than that of the TiN film formed according to the comparative example.

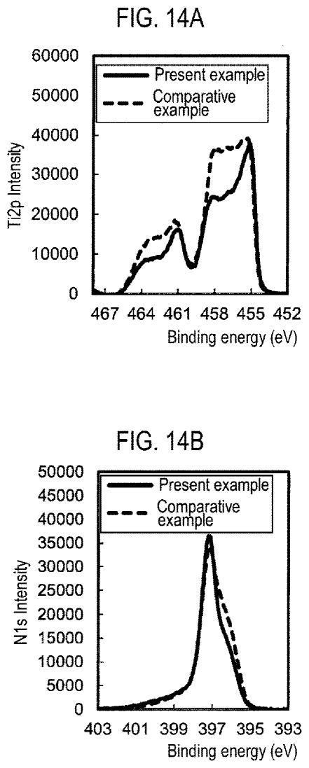

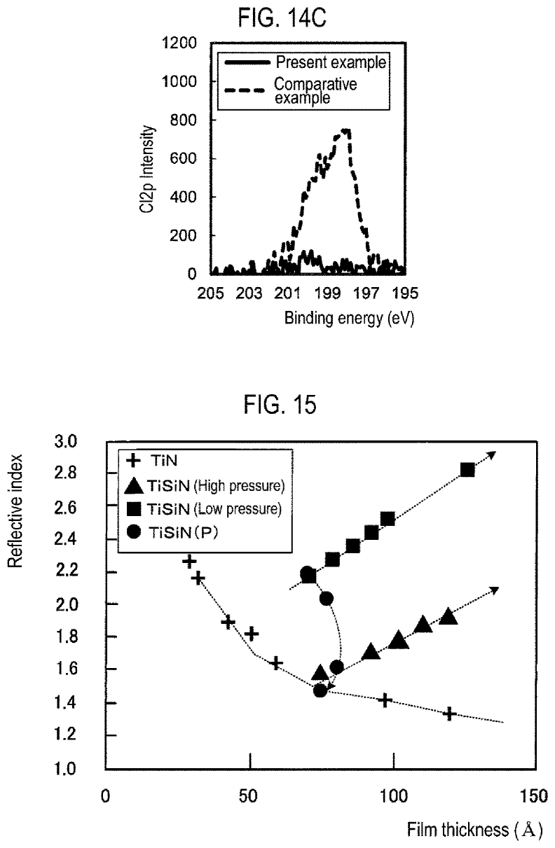

FIGS. 14A to 14C are diagrams illustrating X-ray photoelectron spectroscopy (XPS) spectra of the TiN film formed according to this example and the TiN film formed according to the comparative example. As illustrated in FIGS. 14A and 14B, it could be confirmed that, in the TiN film formed according to the comparative example, the peak was increased near 458 to 459 eV indicative of a Ti—O bond to react with oxygen (O) in the atmosphere. On the other hand, it could be seen that, in the TiN film formed according to this example, the peak was increased near 455 eV indicative of a Ti-bond to reduce a Ti—O bond due to oxygen in the atmosphere. Moreover, as illustrated in FIG. 14C, it could be seen that the Cl residual concentration in the TiN film formed according to this example was lower than that of the TiN film formed according to the comparative example.

That is, it could be confirmed that it is possible to prevent the oxidation of the TiN film by the atmosphere, in addition to lowering the resistivity and the Cl residual concentration in the film, by using this example. This is considered to be because the TiN film formed according to this example is more N-rich than the stoichiometric composition of Ti:N=1:1, to become a film which is difficult to be oxidized. Furthermore, the Cl concentration of the TiN film formed according to this example was 1% or less. This is considered to be because HCl does not exist when the NH₃ gas is supplied, so that NH₃ is more easily adsorbed. Even when HCl exists, NH₃ is consumed in forming ammonium chloride (NH₄Cl) as the byproduct. That is, it could be confirmed that, by reducing HCl, which is a growth inhibiting factor, it is possible to obtain a higher deposition rate than the TiN film formed according to the comparative example.

The Si content (Si concentration) in the TiN film formed according to the present embodiment is about 4%. A mechanism by which the Si content in the TiN film formed according to the present embodiment is significantly reduced will now be described.

FIG. 15 is a diagram illustrating a relationship between a film thickness and a refractive index of the TiN film formed when the SiH₄ gas as the reducing gas of the aforementioned embodiments is supplied with the internal pressure of the process chamber 201 at a low pressure of about 1 Pa to 300 Pa (▪ in FIG. 15) and at a high pressure of about 500 Pa to 2,660 Pa (▴ in FIG. 15), and by changing the low pressure to the high pressure (● in FIG. 15). In FIG. 15, “+” indicates a film thickness dependence of the refractive index of the TiN film. The horizontal axis indicates a film thickness, and the vertical axis indicates a refractive index. It is meant that the higher the refractive index on the vertical axis, the higher the Si content in the film.

According to FIG. 15, it can be confirmed that the Si content (refractive index) in the film can be reduced by setting the internal pressure of the process chamber 201 during the supply of the SiH₄ gas at a high pressure of about 500 Pa to 2,660 Pa. In addition, it can be confirmed that, even in the case of a low pressure of about 1 Pa to 300 Pa and a high pressure of about 500 Pa to 2,660 Pa, if the supply time or the supply flow rate of the SiH₄ gas after the supply stop of the TiCl gas is increased beyond a predetermined value, Si enters the film so that the Si content in the film is increased to change the TiN layer to a TiSiN layer. That is, the Si content (refractive index) can be reduced to form a TiN layer not containing a Si atom, by setting the internal pressure of the process chamber 201 during the supply of the SiH₄ gas at a high pressure which falls within a range of, for example, 130 to 3,990 Pa, specifically 500 to 2,660 Pa, or more specifically 900 to 1,500 Pa, by adjusting the APC valve 243, by adjusting the supply time of the SiH₄ gas at a time which falls within a range of, for example, 0.1 to 60 seconds, specifically 0.5 to 30 seconds, or more specifically 1 to 20 seconds, and by adjusting the supply flow rate of the SiH₄ gas to a flow rate which falls within a range of, for example, 0.1 to 5 slm, specifically 0.5 to 3 slm, or more specifically 1 to 2 slm.

That is, even when the internal pressure of the process chamber 201 during the supply of the SiH₄ gas is a high pressure which falls within a predetermined range, if the supply time of the SiH₄ gas is long or the supply amount thereof is large, the refractive index becomes equal to or higher than when the internal pressure of the process chamber 201 is a low pressure. Therefore, in addition to specifying the pressure range, the supply time and the supply amount may be specified.

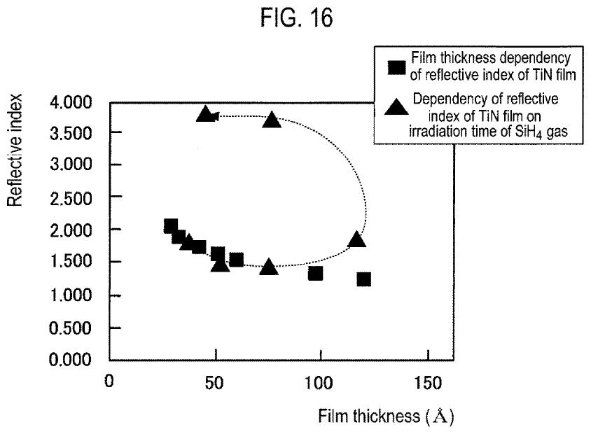

FIG. 16 is a diagram illustrating a critical value of the supply time of the SiH₄ gas as the reducing gas of the aforementioned embodiments. The horizontal axis indicates a film thickness, and the vertical axis indicates a refractive index. In FIG. 16, ▪ indicates a film thickness dependence of the refractive index of the TiN film, and ▴ indicates a dependence of the refractive index of the TiN film on the irradiation time of the SiH₄ gas. At this time, the temperature of the heater 207 was set such that the temperature of the wafer 200 became 475 degrees C. A plot above a plot (▪) of the film thickness dependence of the refractive index of the TiN film illustrated in FIG. 16 indicates that Si is contained. Furthermore, in a plot (▴) of a dependency of the refractive index of the TiN film on the irradiation time of the SiH₄ gas illustrated in FIG. 16, an experiment was conducted by extending the supply time to 5 seconds, 10 seconds, 20 seconds, . . . , 90 seconds in an arrow direction near the film thickness 38 Å. Thus, it could be confirmed that the upper limit value of the supply time of the SiH₄ gas was about 20 seconds.

Furthermore, in the embodiments and the example described above, there has been made a description using TiCl₄ as the precursor gas. However, the present disclosure is not limited thereto but may be applied to a halogen-containing gas such as tungsten hexafluoride (WF₆), tantalum tetrachloride (TaCl₄), tungsten hexachloride (WCl₆), tungsten pentachloride (WCl₅), molybdenum tetrachloride (MoCl₄), silicon tetrachloride (SiCl₄), disilicon hexachloride (Si₂Cl₆) or hexachlorodisilane (HCDS), or a Cl-containing gas in some embodiments and may be applied to films formed using them. Moreover, the present disclosure may be applied to a Si-based gas such as trichlorodisilane (TCS) or the like, in addition to the tantalum (Ta)-based, and may be applied to films formed using them.

In the embodiments and the example described above, there has been made a description using SiH₄ as the reducing gas for reducing HCl. However, the present disclosure is not limited thereto but may be applied to a gas such as, for example, disilane (Si₂H₆), trisdimethylaminosilane (SiH[N(CH₃)₂), diborane (B₂H₆), phosphine (PH₃) or the like, containing H.

Furthermore, in the embodiments and the example described above, there has been made a description using one kind of reducing gas. However, the present disclosure is not limited thereto but two or more kinds of reducing gas may be used.

In addition, in the embodiments and the examples described above, there has been made a description using HCl as the byproduct to be reduced using the reducing gas. However, the present disclosure is not limited thereto but may be applied to a gas such as hydrogen fluoride (HF), hydrogen iodide (HI), bromide hydrogen (HBr) or the like.

Moreover, in the embodiments and the example described above, there have been described a configuration in which the TiCl₄ gas as the precursor gas and the SiH₄ gas as the reducing gas are respectively supplied from the nozzles 410 and 420 into the process chamber 201. However, the present disclosure is not limited thereto but they may be supplied by their premix from one nozzle.

Furthermore, in the embodiments and the example described above, there has been described a configuration in which the reducing gas is supplied simultaneously with or after the supply of the TiCl₄ gas, or simultaneously with or after the supply of the NH₃ gas. However, the present disclosure is not limited thereto but may be applied to a configuration in which a reducing gas is supplied at the time of supplying each of the TiCl₄ gas and the NH₃ gas or after supplying each of the TiCl₄ gas and the NH₃ gas.

Furthermore, in the embodiments and the example described above, there has been described a configuration in which films are formed using a batch-type substrate processing apparatus capable of processing a plurality of substrates at a time. However, the present disclosure is not limited thereto but may be suitably applied to a case where films are formed using a single-wafer-type substrate processing apparatus capable of processing one substrate or several substrates at a time.

According to the present disclosure in some embodiments, it is possible to reduce a film formation inhibiting factor of a metal film by supplying a reducing gas that reacts with a byproduct generated in a film-forming process into a process chamber and discharging it to outside of the process chamber.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) supplying a first gas that contains silicon and halogen to the substrate;
(b) supplying a first reducing gas that contains phosphorus and hydrogen to the substrate;
(c) supplying a second gas to the substrate;
(d) performing (b) and (c), wherein (d) includes a timing of simultaneously performing (b) and (c);
(e) between (a) and (b), performing purging; and
(f) forming a film on the substrate, by performing (a), (e), and (d) a predetermined number of times in an order of (a), (e), and (d).

2. The method according to claim 1, wherein in (d), (b) and (c) are started simultaneously.

3. The method according to claim 1, wherein after (c) is completed, (b) is completed.

4. The method according to claim 2, wherein after (c) is completed, (b) is completed.

5. The method according to claim 1, wherein a time period of (b) is longer than a time period of (c).

6. The method according to claim 1, wherein in (d), after (a) is started, (c) is started.

7. The method according to claim 6, wherein after (c) is completed, (b) is completed.

8. The method according to claim 1, wherein the halogen is chlorine.

9. The method according to claim 1, wherein the second gas is a second reducing gas.

10. The method according to claim 1, wherein the second gas is a second reducing gas that contains nitrogen.

11. A method of manufacturing a semiconductor device, comprising the method of claim 1.

12. A non-transitory computer-readable recording medium storing a program that causes, by a computer, a substrate processing apparatus to perform a process comprising:
(a) supplying a first gas that contains silicon and halogen to a substrate;
(b) supplying a first reducing gas that contains phosphorus and hydrogen-to the substrate;
(c) supplying a second gas to the substrate;
(d) performing (b) and (c), wherein (d) includes a timing of simultaneously performing (b) and (c);
(e) between (a) and (b), performing purging; and
(f) forming a film on the substrate, by performing (a), (e), and (d) a predetermined number of times in an order of (a), (e), and (d).

13. A substrate processing apparatus, comprising:
a first gas supply part configured to supply a first gas that contains silicon and halogen to a substrate;
a second gas supply part configured to supply a first reducing gas that contains phosphorus and hydrogen to the substrate;
a third gas supply part configured to supply a second gas to the substrate; and
a controller configured to be capable of controlling the first gas supply part, the second gas supply part, and the third gas supply part by performing:
(a) supplying the first gas to the substrate;
(b) supplying the first reducing gas to the substrate;
(c) supplying the second gas to the substrate;
(d) performing (b) and (c), wherein (d) includes a timing of simultaneously performing (b) and (c);
(e) between (a) and (b), performing purging; and
(f) forming a film on the substrate, by performing (a), (e), and (d) a predetermined number of times in an order of (a), (e), and (d).
